(19) United States
(12) Patent Application Publication
(10) Pub. No.: US 2008/0067567 A1
(43) Pub. Date: Mar. 20, 2008

(54) SEMICONDUCTOR DEVICE

(75) Inventors: Hiroyuki Kanaya, Yokohama-shi (JP); Iwao Kunishima, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/854,138

(22) Filed: Sep. 12, 2007

(30) Foreign Application Priority Data
Sep. 13, 2006 (JP) 2006-248511

(51) Int. Cl. H01L 27/105

(52) U.S. Cl. 257/295; 257/E27.081

(57) ABSTRACT

According to an aspect of the present invention, there is provided a semiconductor device including: a substrate; an insulating film disposed on the substrate; a plug electrode disposed in the insulating film; and a capacitor unit including: a lower electrode that is disposed on the insulating film and that covers a top face of the plug electrode, a ferroelectric film disposed on the lower electrode, a first upper electrode disposed on the ferroelectric film, and a second upper electrode disposed on the ferroelectric film and separated from the first upper electrode; wherein the first upper electrode covers a center of the plug electrode as viewed in a direction perpendicular to a surface of the semiconductor substrate.

### CROSS-REFERENCE TO RELATED APPLICATIONS

The entire disclosure of Japanese Patent Application No.2006-248511 filed on Sep. 13, 2006 including specification, claims, drawings and abstract is incorporated herein by reference in its entirety.

### BACKGROUND OF THE INVENTION

1. Field of the Invention

An aspect of the present invention relates to a semiconductor device and, more particularly, to a semiconductor device featuring a miniaturized capacitor structure of a chain ferroelectric memory.

2. Description of the Related Art

With the advancement of the integration of ferroelectric memories (FeRAMs), it has become indispensable to form ferroelectric capacitors by carrying out Single-Mask Photo-Engraving Process (PEP) (hereunder sometimes referred to as a “1-Mask-1-PEP”) to perform collective patterning processing. A Chain-FeRAM™, to which the structure (hereunder sometimes referred to as a “1-PEP_FeRAM capacitor structure”) of the ferroelectric capacitor is applied, has been devised. A capacitor structure for the Chain-FeRAM™ has been proposed, in which lower electrodes are physically contacted with one another by adjusting etching conditions and the distance between the capacitors so as to reduce a cell size (see, for example, JP-A-2001-257320 and U.S. Pat. No. 6,762,065).

JP-A-2001-257320 and U.S. Pat. No. 6,762,065 disclose a structure in which a plug electrode electrically connected to a diffusion layer disposed in a semiconductor substrate is placed at the central portion between a pair of ferroelectric capacitors. In a case where the ferroelectric capacitors can be formed so that the capacitor sizes thereof are large, and that the shape of the capacitors is substantially a square (or a rectangle), even when a slight misalignment occurs, the surface of the plug electrode is covered by the lower electrodes. After the capacitors are formed in the FeRAM, a high-temperature recovery oxidation process is frequently employed to recover the FeRAM from damages, such as processing damages. Because a tungsten (W) plug electrode is covered by the lower electrodes, a problem of an oxidative burst of the plug electrode does not occur.

On the other hand, in a case where the miniaturization of the capacitors is advanced, and where the capacitor size becomes closer to a minimum size allowed by a design rule size, for example, the capacitor size is about twice the minimum size, a lithographic shape is a circle. Thus, the shape of the capacitor is also a circle.

In this case, a groove is formed in a connecting portion between the pair of ferroelectric capacitors. Consequently, a surface of the W plug electrode placed at the central portion between the pair of ferroelectric capacitors is exposed due to lithographic misalignment. Accordingly, an oxidative burst of the W plug electrode occurs by the high-temperature recovery oxidation process, so that the fabrication yield is reduced.

### SUMMARY OF THE INVENTION

According to an aspect of the present invention, there is provided a semiconductor device including: a semiconductor substrate; a transistor including: a first diffusion layer disposed on the semiconductor substrate, a second diffusion layer disposed on the semiconductor substrate, a gate insulating film disposed between the first diffusion layer and the second diffusion layer and on the semiconductor substrate, and a gate electrode disposed on the gate insulating film; an interlayer insulating film disposed on the semiconductor substrate and on the transistor; a plug electrode that is connected to the first diffusion layer and disposed in the interlayer insulating film; and a capacitor unit including: a lower electrode that is disposed on the interlayer insulating film and that covers a top face of the plug electrode, a ferroelectric film disposed on the lower electrode, a first upper electrode disposed on the ferroelectric film, and a second upper electrode disposed on the ferroelectric film and separated from the first upper electrode; wherein the first upper electrode covers a center of the plug electrode as viewed in a direction perpendicular to a surface of the semiconductor substrate.

According to another aspect of the present invention, there is provided a semiconductor device including: a semiconductor substrate; a transistor including: a first diffusion layer disposed on the semiconductor substrate, a second diffusion layer disposed on the semiconductor substrate, a gate insulating film disposed between the first diffusion layer and the second diffusion layer and on the semiconductor substrate, and a gate electrode disposed on the gate insulating film; an interlayer insulating film disposed on the semiconductor substrate and on the transistor; a plug electrode that is connected to the first diffusion layer and disposed in the interlayer insulating film; and a capacitor unit including: a lower electrode that is disposed on the interlayer insulating film to cover a top face of the plug electrode such that a center of the lower electrode is arranged on the top face, a ferroelectric film disposed on the lower electrode, a first upper electrode disposed on the ferroelectric film, and a second upper electrode disposed on the ferroelectric film and separated from the first upper electrode; wherein the lower electrode including: a first circular portion disposed oppositely to the first upper electrode and having a diameter of about R, and a second circular portion electrically connected with the first circular portion and disposed oppositely to the second upper electrode, the second circular portion having the diameter of about R; wherein the plug electrode is formed in a rectangular shape having a long side length of about a and a short side length of about b; and wherein R, a and b satisfy R>2b and 2R>a>R.

According to still another aspect of the present invention, there is provided a semiconductor device including: a semiconductor substrate; an interlayer insulating film disposed on the semiconductor substrate; a plug electrode disposed in the interlayer insulating film; and a capacitor unit including: a lower electrode that is disposed on the interlayer insulating film and connected with the plug electrode, a ferroelectric film disposed on the lower electrode, a first upper electrode disposed on the ferroelectric film, and a second upper electrode disposed on the ferroelectric film and separated from the first upper electrode; wherein the lower electrode including: a first circular portion that covers a top face of the plug electrode and that is opposite to the first upper electrode, and a second circular portion that is electrically connected with the first circular portion and that is opposite to the second upper electrode; and wherein the plug electrode is disposed underneath only the first circular portion.

### BRIEF DESCRIPTION OF THE DRAWINGS

Embodiment may be described in detail with reference to the accompanying drawings, in which:

FIG. 1A is a schematic cross-sectional view illustrating the configuration of a semiconductor device according to a first embodiment, and

FIG. 1B is a schematic pattern plan view illustrating the vicinity of each of a capacitor portion CAP and a contact plug portion CP of the semiconductor device according to the first embodiment;

FIG. 2 is a schematic pattern plan view illustrating the semiconductor device according to the first embodiment;

FIG. 3 is a schematic cross-sectional view illustrating the configuration of the semiconductor device according to the first embodiment, which is taken along line III-III shown in FIG. 2;

FIG. 4 is a schematic cross-sectional view illustrating the configuration of a semiconductor device according to a second embodiment;

FIG. 5 is a schematic pattern plan view illustrating the semiconductor device according to the second embodiment;

FIG. 6 is a schematic cross-sectional view illustrating the configuration of the semiconductor device according to the second embodiment, which is taken along line VI-VI shown in FIG. 5;

FIG. 7A is a schematic cross-sectional view illustrating the configuration of the vicinity of each of a capacitor portion CAP and a contact plug portion CP of a semiconductor device according to a third embodiment, and

FIG. 7B is a schematic pattern plan view illustrating the vicinity of each of the capacitor portion CAP and the contact plug portion CP of the semiconductor device according to the third embodiment;

FIG. 8A is a schematic cross-sectional view illustrating the configuration of a semiconductor device according to a fourth embodiment, and

FIG. 8B is a schematic pattern plan view illustrating the vicinity of each of a capacitor portion CAP and a contact plug portion CP of the semiconductor device according to the fourth embodiment;

FIG. 9A is a schematic cross-sectional view illustrating the configuration of a semiconductor device according to a fifth embodiment, and

FIG. 9B is a schematic pattern plan view illustrating the vicinity of each of a capacitor portion CAP and a contact plug portion CP of the semiconductor device according to the fifth embodiment;

FIG. 10 is a schematic pattern plan view illustrating the semiconductor device according to the fifth embodiment;

FIG. 11 is a schematic cross-sectional view illustrating the configuration of the semiconductor device according to the fifth embodiment, which is taken along line XI-XI shown in FIG. 9;

FIG. 12 is a circuit view illustrating the configuration of a Chain-FeRAM™ cell block to which each of the semiconductor devices according to the first to fifth embodiments can be applied; and

FIG. 13 is a schematic block view illustrating the configuration of a Chain-FeRAM™ cell array that is an example of a memory cell array to which each of the semiconductor devices according to the first to fifth embodiments can be applied.

### DETAILED DESCRIPTION OF THE INVENTION

First to fifth embodiments of the invention are described below with reference to the accompanying drawings. In the following description of the drawings, same or similar reference numerals designate same or similar components. It should be noted that the drawings are schematic, and that the relation between a thickness and each of planar dimensions, and ratios among thicknesses of layers differ from actual relation and ratios. Actual thickness and dimensions should be determined in consideration of the following descriptions. Also, it is apparent that the relationships and ratios among the dimensions of components vary with the drawings.

The following first to fifth embodiments are exemplary embodiments of devices implementing technical ideas of this invention. The technical ideas of this invention do not limit the materials, shapes, configurations, and arrangements of components to those described below. Various alterations of the technical ideas of the invention can be made within the scope of the appended claims.

### First Embodiment

Basic Configuration

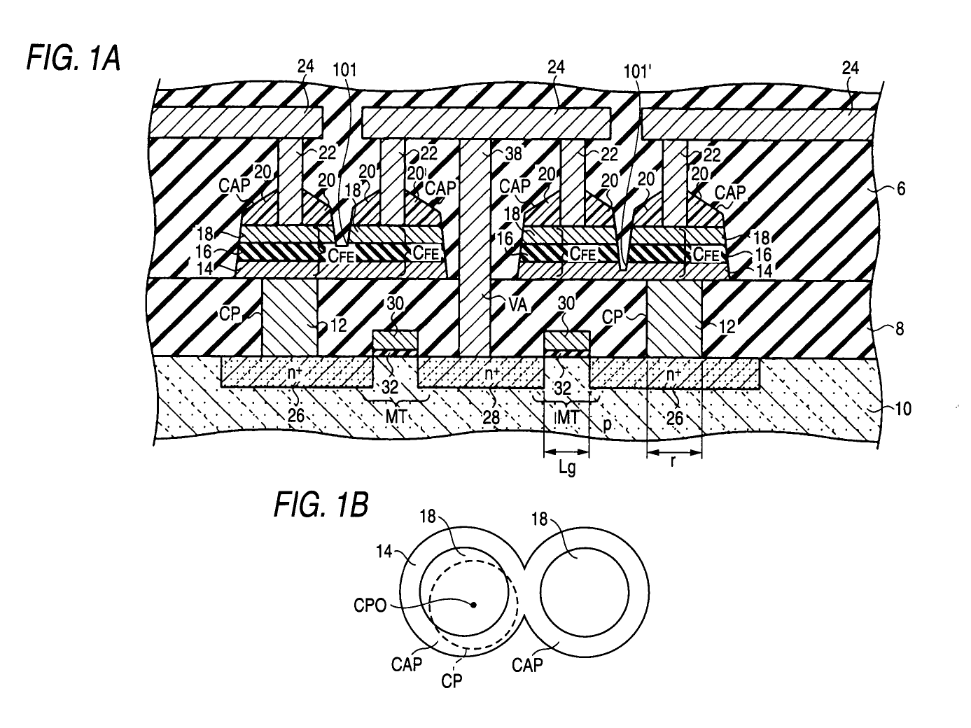

FIG. 1A schematically and cross-sectionally illustrates the configuration of a semiconductor device according to a first embodiment. FIG. 1B illustrates a schematic planar pattern of the vicinity of each of a capacitor CAP and a contact plug portion CP of the semiconductor device according to the first embodiment.

As shown in FIG. 1A, the semiconductor device according to the first embodiment includes a semiconductor substrate 10, transistors MT disposed on the semiconductor substrate 10, each of which has source-drain diffusion layers 26, 28, a gate insulating film 32 placed on the semiconductor substrate 10 between the source-drain diffusion layers 26 and 28, and a gate electrode 30 placed on the gate insulating film 32, an interlayer insulating film 8 disposed on the transistors MT, a plug electrode 12 disposed on one 26 of the source-drain diffusion layers that each of the transistors has, and a plurality of ferroelectric capacitors C_{FE}, each of which includes a lower electrode 14, a ferroelectric film 16, and an upper electrode 18. The plurality of ferroelectric capacitors are paired two by two so that the ferroelectric capacitors C_{FE} of each pair have a common one of the lower electrodes 14 and individual ones of the upper electrodes 18, that the plug electrode is disposed just under one of each of the pairs of the ferroelectric capacitors C_{FE}, and that the entire surface of each of the plug electrodes 12 is covered by the lower electrodes 14.

As shown in FIG. 1A, an interlayer insulating film 6 is disposed on the interlayer insulating film 8. A plurality of capacitors CAP having the lower electrode 14, the ferroelectric film 16 and the upper electrode 18, are disposed in the interlayer insulating film 6 by being embedded therein.

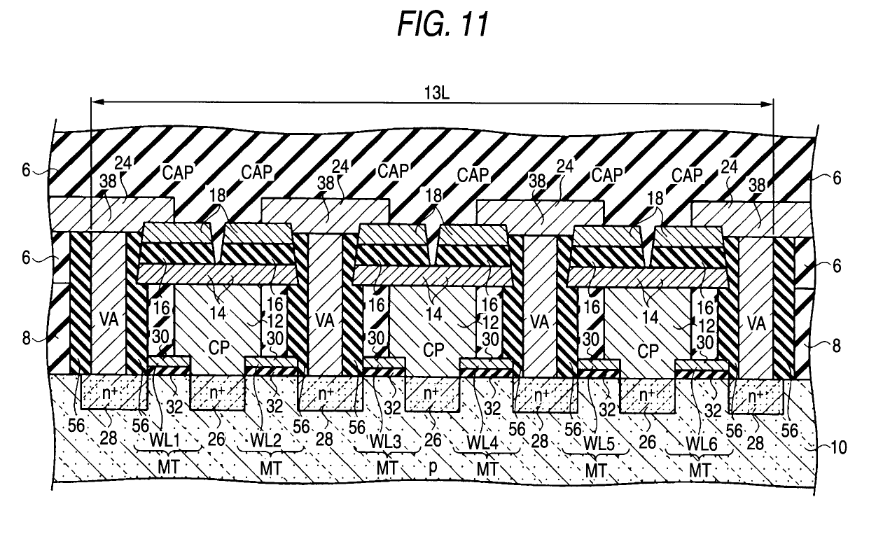

As shown in FIG. 1A, a viahole electrode 22 is placed through a contact hole formed in a hard mask 20 that is disposed on the upper electrode 18. The via hole electrode 22 is connected to a wiring electrode 24, together with a viahole electrode 38 placed on the other 28 of the source-drain diffusion layers 26 and 28. Thus, a Chain-FeRAM™ is constituted. FIG. 11 illustrates the circuit configuration of the Chain-FeRAM™, which will be described later.

As is illustrated in the schematic cross-sectional view of the semiconductor according to the first embodiment shown in FIG. 1A, each of the pair of the ferroelectric capacitors C_{FE} are physically connected with each other through a part of the ferroelectric film 16 and the lower electrode 14.

In this case, a depression 101 is formed on the upper surface of the ferroelectric film 16, as shown in a left part of FIG. 1A.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

In this case, a depression 101′ is formed on the upper surface of the lower electrode 14, as shown in a right part of FIG. 1A.

The ferroelectric capacitors of each pair share the lower electrode 14 in common. Thus, each of pair of the capacitors CAP is disposed to be in physically contact with each other through the shared portion of the lower electrode 14. Also, the contact plug portion CP is disposed just under one of the paired ferroelectric capacitors. Thus, the contact plug portion CP is disposed to be covered by one of the capacitor portions CAP.

In this case, a center CPO of the contact plug portion CP (the plug electrode 12) is covered by one of the upper electrodes 18 as viewed in a direction perpendicular to a surface of the semiconductor substrate 10, as shown in FIG. 1B. As shown in FIGS. 1A and 1B, the plug electrode 12 is formed substantially in a cylindrical shape having the diameter of about r. The memory cell transistor MT has the gate length of about Lg. The diameter r of the plug electrode 12 is equal to or larger than the gate length Lg of the memory cell transistor MT.

In the capacitor structure of the semiconductor device according to the first embodiment, as shown in FIGS. 1A and 1B, the electrically conductive plug electrode 12 is disposed just under the capacitor portion CAP of one of the paired ferroelectric capacitors having the lower electrode 14 in common. This plug electrode 12 is electrically connected to the diffusion layer 26 that is one of the source-drain diffusion layers 26, 28.

In a case where the capacitor structure of the semiconductor device according to the first embodiment is employed, the fabrication yield is enhanced with respect to to the configuration in which the plug electrode is disposed substantially at the center of a pair of ferroelectric capacitors having the lower electrode 14 and the ferroelectric film 16 in common. This is because the failure of the plug due to oxidation is reduced.

For example, SrRuO₃ or IrO₂ can be used as the material of the upper electrode 18 of the ferroelectric capacitor C_{FE}. For instance, PZT(Pb(Zr_{X}Ti_{1-X})O₃) can be used as the material of the ferroelectric film 16 of the ferroelectric capacitor C_{FE}. For example, SrRuO₃, Pt, IrO₂, Ir, Ti can be used as the lower electrode 14 of the ferroelectric capacitor C_{FE}.

The hard mask 20 is disposed on the ferroelectric capacitor C_{FE} so as to process collectively the ferroelectric capacitor structures including the upper electrode 18, the ferroelectric film 16, and the lower electrode 14 by performing the 1-Mask-1-PEP. A silicon dioxide film (SiO₂), an aluminum oxide film (Al_{X}O_{Y}) a zirconium oxide film (ZrO_{X}), a titanium oxide film (TiO_{X}) a titanium aluminum nitride film (TiAl_{X}N_{Y}), a titanium nitride film (Ti_{X}N_{Y}), a titanium aluminum nitride oxide film (TiAl_{X}N_{Y}O_{Z}), a titanium nitride oxide film (Ti_{X}N_{Y}O_{Z}), or a multilayer film including these films can be used as the material of the hard mask 20. It is advisable to select a material, whose etching-selectivity is larger than that of each of the upper electrode 18, the ferroelectric film 16, and the lower electrode 14, as the material of the hard mask 20.

Also, it is advisable to set the distance between the ferroelectric capacitors of each pair, the lower electrodes 14 of which are connected to a same diffusion layer 26, so that the lower electrodes 14 are physically contacted with each other after the capacitor portions CAP are collectively processed by performing the 1-MASk-1-PEP.

Consequently, it is sufficient to dispose one contact plug portion CP corresponding to a pair of capacitor portions CAP, without disposing one contact plug portion CP corresponding to one capacitor portion CAP. Thus, the memory cell size can be reduced.

At that time, each of the contact plug portions CP is disposed under one of the capacitor portions CAP of an associated pair so that the entire surface of the plug electrode 12 is covered by the lower electrode 14, and that the surface of the plug electrode 12 is surely disposed immediately under the lower electrode 14.

Occurrences of the explosion of the W-plug, and high-increase in the resistance of each of the plug electrode 12 and the lower electrode 14 can be suppressed, and the fabrication yield can be enhanced by applying this configuration to the device, for example, in a case where the W-plug electrode is employed as the plug electrode 12.

Most Dense Configuration

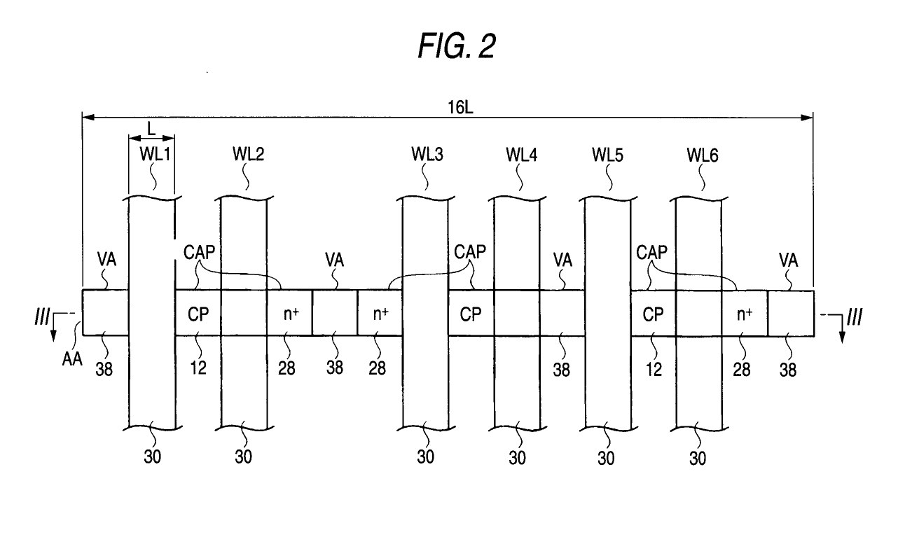

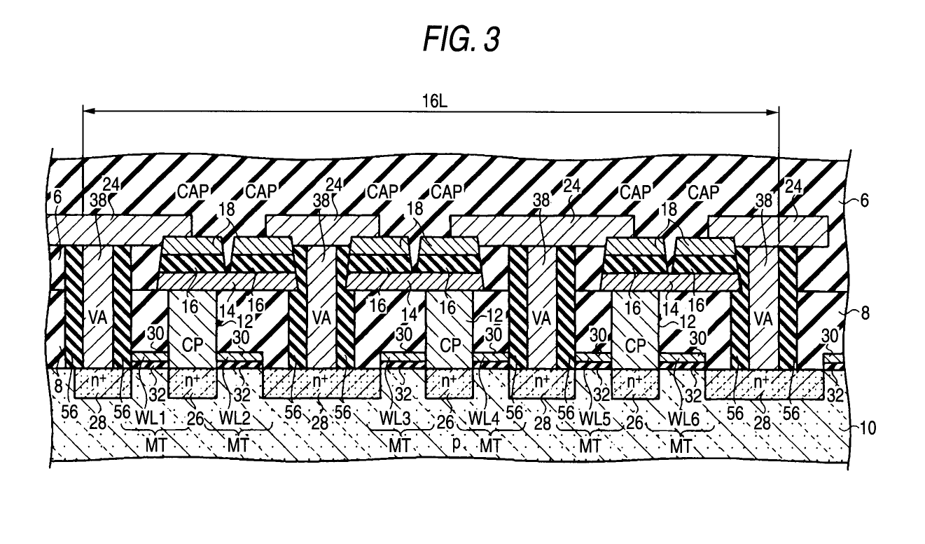

In a case where the semiconductor device according to the first embodiment is configured in the most dense configuration, and where, for example, six memory cell transistors MT are disposed in series in a Chain-FeRAM™ structure, the schematic planar pattern configuration is such that the semiconductor device has an active region AA extending in a column direction and also has word lines WL1 to WL6 extending in a row direction perpendicular to the active region AA, as shown in FIG. 2. FIG. 3 is a schematic cross-sectional view illustrating the configuration of the semiconductor device according to the first embodiment, which is taken along line III-III shown in FIG. 2.

In FIGS. 1A to 3, a region to be shown as the viahole electrode 38 is designated as a viahole contact portion VA. Also, a region to be shown as the plug electrode 12 is designated as a contact plug portion CP. Additionally, a region to be shown as the ferroelectric capacitor C_{FE} including the lower electrode 14, the ferroelectric film 16, and the upper electrode 18, is designated as the capacitor portion CAP.

The semiconductor device according to the first embodiment employs a pattern configuration, which is symmetric with respect to the viahole contact portion VA extending in the row direction perpendicular to the column direction, as illustrated in FIGS. 1A to 3.

In a case where the six memory cell transistors MT are disposed in series in the Chain-FeRAM™ configuration, and where L denotes the minimum line width, the memory cell transistors MT are placed within a dimension of 16L, as illustrated in FIG. 2. The source-drain diffusion layers 26, 28 of each of the memory cell transistors MT, are arranged in the active region AA. Also, a channel region corresponding to each of portions of the semiconductor substrate 10, each of which is provided between the associated source-drain diffusion layers 26, 28, is placed in the active region AA. In the example shown in FIG. 2, the channel region is disposed in an intersection portion at which the active region AA intersects with each of the word lines WL1 to WL6. Although FIG. 2 shows only one active region AA of the example, a plurality of active regions AA extend in the column direction in parallel to one another on a memory cell array.

As shown in FIG. 3, the example of the semiconductor device according to the first embodiment in the most dense configuration, in which the six memory cell transistors MT are disposed in series in the Chain-FeRAM™ structure, includes a semiconductor substrate 10, transistors MT disposed on the semiconductor substrate 10, each of which has the source-drain diffusion layers 26, 28, a gate insulating film 32 placed on the semiconductor substrate 10 between the source-drain diffusion layers 26 and 28, and the gate electrode 30 placed on the gate insulating film 32, the interlayer insulating film 8 disposed on the transistors MT, the plug electrode 12 disposed on one 26 of the source-drain diffusion layers that each of the transistors has, and a plurality of ferroelectric capacitors C_{FE}, each of which includes a lower electrode 14, a ferroelectric film 16, and an upper electrode 18. The plurality of ferroelectric capacitors are paired two by two so that the ferroelectric capacitors of each pair have a common one of the lower electrodes 14 and individual ones of the upper electrodes 18, that the plug electrode 12 is disposed just under one of each of the pairs of the ferroelectric capacitors C_{FE}, and that the entire surface of each of the plug electrodes 12 is covered by the lower electrodes 14.

In this case, a center CPO of the contact plug portion CP (the plug electrode 12) is covered by one of the upper electrodes 18 as viewed in a direction perpendicular to a surface of the semiconductor substrate 10. The plug electrode 12 is formed substantially in a cylindrical shape having the diameter of about r. The memory cell transistor MT has the gate length of about A. The diameter r of the plug electrode 12 is equal to or larger than the gate length Lq of the memory cell transistor MT.

Also, as shown in FIG. 3, the interlayer insulating film 6 is disposed on the interlayer insulating film 8. A plurality of capacitor portions CAP, each of which includes the lower electrode 14, the ferroelectric film 16 and the upper electrode 18, are disposed by being embedded in the interlayer insulating film 6.

Additionally, as shown in FIG. 3, the wiring electrode 24 is disposed on and connected to the upper electrode 18, the wiring electrode 24 is connected to the via hole electrode 38 placed on the other 28 of the source-drain diffusion layers 26, 28 to be sandwiched by the side wall insulating films 56, and thereby the Chain-FeRAM™ is configured.

Each of the pair of the ferroelectric capacitors C_{FE} are physically connected with each other through a part of the ferroelectric film 16 and the lower electrode 14.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

In the semiconductor device according to the first embodiment, a minute capacitor structure can be provided, which is used in a Chain-FeRAM™ having a 1-PEP_FeRAM capacitor structure, and which enhances the fabrication yield thereof.

### Second Embodiment

Basic configuration

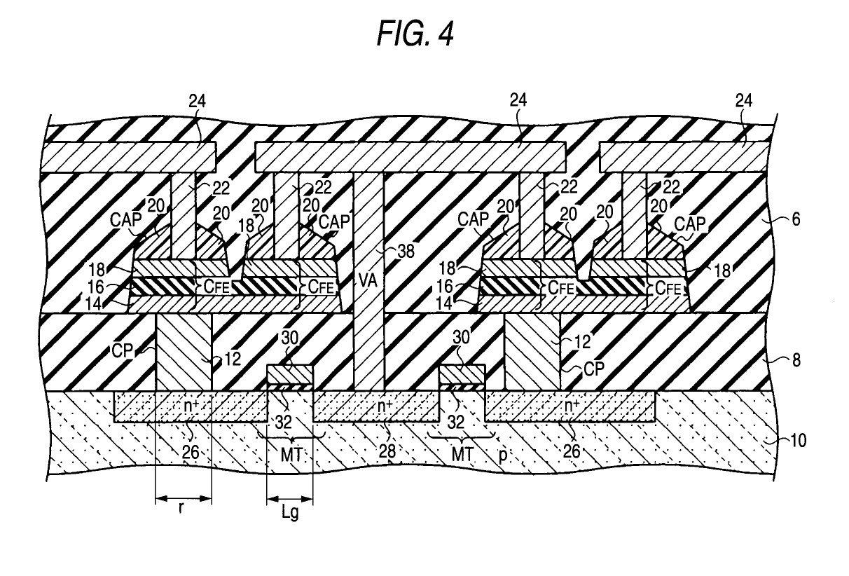

FIG. 4 schematically and cross-sectionally illustrates the configuration of a semiconductor device according to a second embodiment. The semiconductor device according to the second embodiment has a configuration similar to that of the semiconductor device according to the first embodiment. However, the semiconductor device according to the second embodiment has the configuration in which the position of the contact plug portion CP with respect to the pair of different capacitor portions is changed from the semiconductor device according to the first embodiment. A method of positioning the contact plug portion CP may be selected to reduce the memory cell size as small as possible.

The semiconductor device according to the first embodiment employs a pattern configuration, which is symmetric with respect to the viahole contact portion VA extending in the row direction perpendicular to the column direction, as illustrated in FIGS. 1A to 3. In contrast, the semiconductor device according to the second embodiment does not employ such pattern. The semiconductor device according to the second embodiment employs a certain repetitive pattern configuration, as illustrated in FIGS. 4 to 6. The density of the semiconductor device according to the second embodiment is similar to that of the semiconductor device according to the first embodiment, as will be described later.

As shown in FIG. 4, the semiconductor device according to the second embodiment includes a semiconductor substrate 10, transistors MT disposed on the semiconductor substrate 10, each of which has the source-drain diffusion layers 26, 28, a gate insulating film 32 placed on the semiconductor substrate 10 between the source-drain diffusion layers 26 and 28, and the gate electrode 30 placed on the gate insulating film 32, the interlayer insulating film 8 disposed on the transistors MT, the plug electrode 12 disposed on one 26 of the source-drain diffusion layers that each of the transistors has, and a plurality of ferroelectric capacitors C_{FE}, each of which include a lower electrode 14, a ferroelectric film 16, and an upper electrode 18. The plurality of ferroelectric capacitors are paired two by two so that the ferroelectric capacitors of each pair have a common one of the lower electrodes 14 and individual ones of the upper electrodes 18, that the plug electrode 12 is disposed just under one of each of the pairs of the ferroelectric capacitors C_{FE}, and that the entire surface of each of the plug electrodes 12 is covered by the lower electrodes 14.

In this case, a center CPO of the contact plug portion CP (the plug electrode 12) is covered by one of the upper electrodes 18 as viewed in a direction perpendicular to a surface of the semiconductor substrate 10. The plug electrode 12 is formed substantially in a cylindrical shape having the diameter of about r. The memory cell transistor MT has the gate length of about Lg. The diameter r of the plug electrode 12 is equal to or larger than the gate length Lg of the memory cell transistor MT.

Also, as shown in FIG. 4, the interlayer insulating film 6 is disposed on the interlayer insulating film 8. A plurality of capacitor portions CAP, each of which includes the lower electrode 14, the ferroelectric film 16 and the upper electrode 18, are disposed by being embedded in the interlayer insulating film 6.

Additionally, as shown in FIG. 4, a viahole electrode 22 is placed through a contact hole formed in a hard mask 20 that is disposed on the upper electrode 18. The viahole electrode 22 is connected to a wiring electrode 24, together with a viahole electrode 38 placed on the other 28 of the source-drain diffusion layers 26 and 28. Thus, a Chain-FeRAM™ is constituted.

As illustrated in the schematic cross-sectional view of the semiconductor according to the second embodiment shown in FIG. 4, each of the pair of the ferroelectric capacitors C_{FE} are physically connected with each other through a part of the ferroelectric film 16 and the lower electrode 14.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

The ferroelectric capacitors of each pair share the lower electrode 14 in common. Thus, each of pair of the capacitors CAP is disposed to be in physically contact with each other through the shared portion of the lower electrode 14. Also, the contact plug portion CP is disposed just under one of the paired ferroelectric capacitors. Thus, the contact plug portion CP is disposed to be covered by one of the capacitor portions CAP.

In the capacitor structure of the semiconductor device according to the second embodiment, as shown in FIG. 4, the electrically conductive plug electrode 12 is disposed just under the capacitor portion CAP of one of the paired ferroelectric capacitors having the lower electrode 14 in common. This plug electrode 12 is electrically connected to the diffusion layer 26 that is one of the source-drain diffusion layers 26, 28.

In a case where the capacitor structure of the semiconductor device according to the second embodiment is employed, the fabrication yield is enhanced with respect to the configuration in which the plug electrode is disposed substantially at the center of a pair of ferroelectric capacitors having the lower electrode 14 and the ferroelectric film 16 in common.

For example, SrRuO₃ or IrO₂ can be used as the material of the upper electrode 18 of the ferroelectric capacitor C_{FE}. For instance, PZT(Pb(Zr_{X}Ti_{1-X})O₃) can be used as the material of the ferroelectric film 16 of the ferroelectric capacitor C_{FE}. For example, SrRuO₃, Pt, IrO₂, Ir, Ti can be used as the lower electrode 14 of the ferroelectric capacitor C_{FE}.

The hardmask 20 is disposed on the ferroelectric capacitor C_{FE} so as to process collectively the ferroelectric capacitor structures including the upper electrode 18, the ferroelectric film 16, and the lower electrode 14 by performing the 1-Mask-1-PEP. Incidentally, a silicon dioxide film (SiO₂), an aluminum oxide film (Al_{X}O_{Y}) a zirconium oxide film (ZrO_{X}), a titanium oxide film (TiO_{X}), a titanium aluminum nitride film (TiAl_{X}N_{Y}), a titanium nitride film (Ti_{X}N_{Y}), a titanium aluminum nitride oxide film (TiAl_{X}N_{Y}O_{Z}), a titanium nitride oxide film (Ti_{X}N_{Y}O_{Z}), or a multilayer film including these films can be used as the material of the hard mask 20. It is advisable to select a material, whose etching-selectivity is larger than that of each of the upper electrode 18, the ferroelectric film 16, and the lower electrode 14, as the material of the hard mask 20.

Also, it is advisable to set the distance between the ferroelectric capacitors of each pair, the lower electrodes 14 of which are connected to a same diffusion layer 26, so that the lower electrodes 14 are physically contacted with each other after the capacitor portions CAP are collectively processed by performing the 1-MASk-1-PEP.

Consequently, it is sufficient to dispose one contact plug portion CP corresponding to a pair of capacitor portions CAP, without disposing one contact plug portion CP corresponding to one capacitor portion CAP. Thus, the memory cell size can be reduced.

At that time, each of the contact plug portions CP is disposed under one of the capacitor portions CAP of an associated pair so that the entire surface of the plug electrode 12 is covered by the lower electrode 14, and that the surface of the plug electrode 12 is surely disposed immediately under the lower electrode 14.

Occurrences of the explosion of the W-plug, and high-increase in the resistance of each of the plug electrode 12 and the lower electrode 14 can be suppressed, and the fabrication yield can be enhanced by applying this configuration to the device, for example, in a case where the W-plug electrode is employed as the plug electrode 12.

Most Dense Configuration

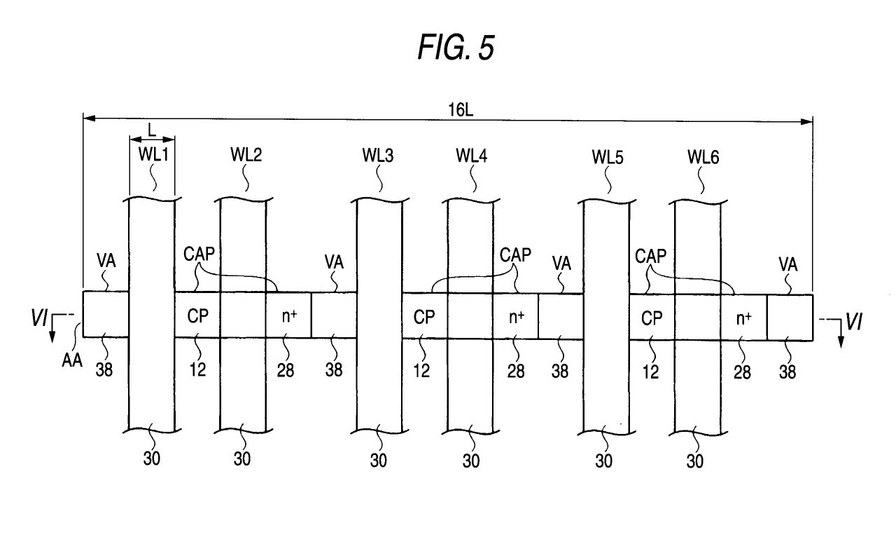

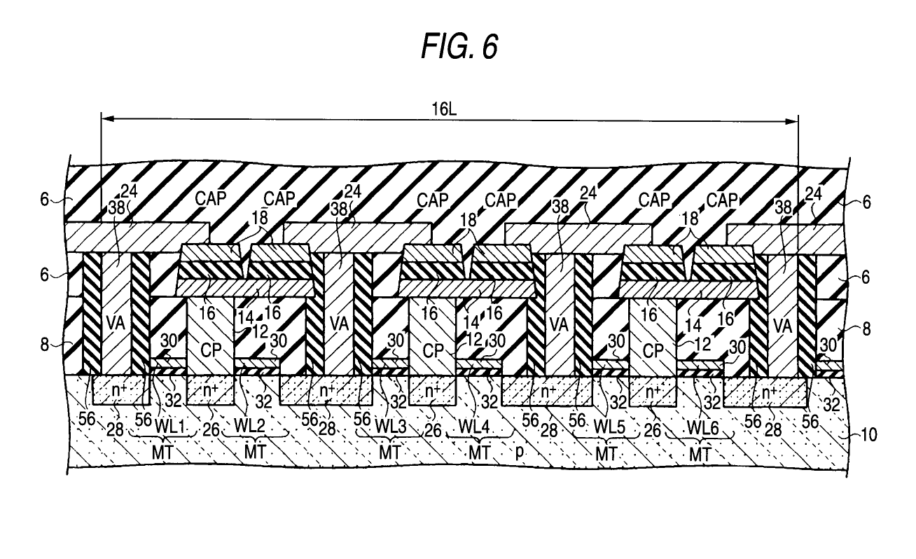

In a case where the semiconductor device according to the second embodiment is configured in the most dense configuration, and where, for example, six memory cell transistors MT are disposed in series in a Chain-FeRAM™ structure, the schematic planar pattern configuration is such that the semiconductor device has an active region AA extending in a column direction and also has word lines WL1 to WL6 extending in a row direction perpendicular to the active region AA, as shown in FIG. 5. FIG. 6 is a schematic cross-sectional view illustrating the configuration of the semiconductor device, which is taken along line VI-VI shown in FIG. 5.

In FIGS. 4 to 6, a region to be shown as the via hole electrode 38 is designated as a via hole contact portion VA. Also, a region to be shown as the plug electrode 12 is designated as a contact plug portion CP. Additionally, a region to be shown as the ferroelectric capacitor C_{FE} including the lower electrode 14, the ferroelectric film 16, and the upper electrode 18, is designated as the capacitor portion CAP.

In a case where the six memory cell transistors MT are disposed in series in the Chain-FeRAM™ configuration, and where L denotes the minimum line width, the memory cell transistors MT are placed within a dimension of 16L, as illustrated in FIG. 5. The source-drain diffusion layers 26, 28 of each of the memory cell transistors MT, are arranged in the active region AA. Also, a channel region corresponding to each of portions of the semiconductor substrate 10, each of which is provided between the associated source-drain diffusion layers 26, 28, is placed in the active region AA. In the example shown in FIG. 5, the channel region is disposed in an intersection portion at which the active region AA intersects with each of the word lines WL1 to WL6. Although FIG. 5 shows only one active region AA of the example, a plurality of active regions AA extend in the column direction in parallel to one another on a memory cell array.

As shown in FIG. 6, the example of the semiconductor device according to the second embodiment in the most dense configuration, in which the six memory cell transistors MT are disposed in series in the Chain-FeRAM™ structure, includes a semiconductor substrate 10, transistors MT disposed on the semiconductor substrate 10, each of which has the source-drain diffusion layers 26, 28, a gate insulating film 32 placed on the semiconductor substrate 10 between the source-drain diffusion layers 26 and 28, and the gate electrode 30 placed on the gate insulating film 32, the interlayer insulating film 8 disposed on the transistors MT, the plug electrode 12 disposed on one 26 of the source-drain diffusion layers that each of the transistors has, and a plurality of ferroelectric capacitors C_{FE}, each of which includes a lower electrode 14, a ferroelectric film 16, and an upper electrode 18. The plurality of ferroelectric capacitors are paired two by two so that the ferroelectric capacitors of each pair have a common one of the lower electrodes 14 and individual ones of the upper electrodes 18, that the plug electrode 12 is disposed just under one of each of the pairs of the ferroelectric capacitors C_{FE}, and that the entire surface of each of the plug electrodes 12 is covered by the lower electrodes 14.

In this case, a center CPO of the contact plug portion CP (the plug electrode 12) is covered by one of the upper electrodes 18 as viewed in a direction perpendicular to a surface of the semiconductor substrate 10. The plug electrode 12 is formed substantially in a cylindrical shape having the diameter of about r. The memory cell transistor MT has the gate length of about Lg. The diameter r of the plug electrode 12 is equal to or larger than the gate length Lg of the memory cell transistor MT.

Also, as shown in FIG. 6, the interlayer insulating film 6 is disposed on the interlayer insulating film 8. A plurality of capacitor portions CAP, each of which includes the lower electrode 14, the ferroelectric film 16 and the upper electrode 18, are disposed by being embedded in the interlayer insulating film 6.

Additionally, as shown in FIG. 6, the wiring electrode 24 is disposed on and connected to the upper electrode 18, the wiring electrode 24 is connected to the via hole electrode 38 placed on the other 28 of the source-drain diffusion layers 26, 28 to be sandwiched by the side wall insulating films 56, and thereby the Chain-FeRAM™ is configured.

Each of the pair of the ferroelectric capacitors C_{FE} are physically connected with each other through a part of the ferroelectric film 16 and the lower electrode 14.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

In the semiconductor device according to the second embodiment, a minute capacitor structure can be provided, which is used in a Chain-FeRAM™ having a 1-PEP_FeRAM capacitor structure, and which enhances the fabrication yield thereof.

### Third Embodiment

Basic configuration

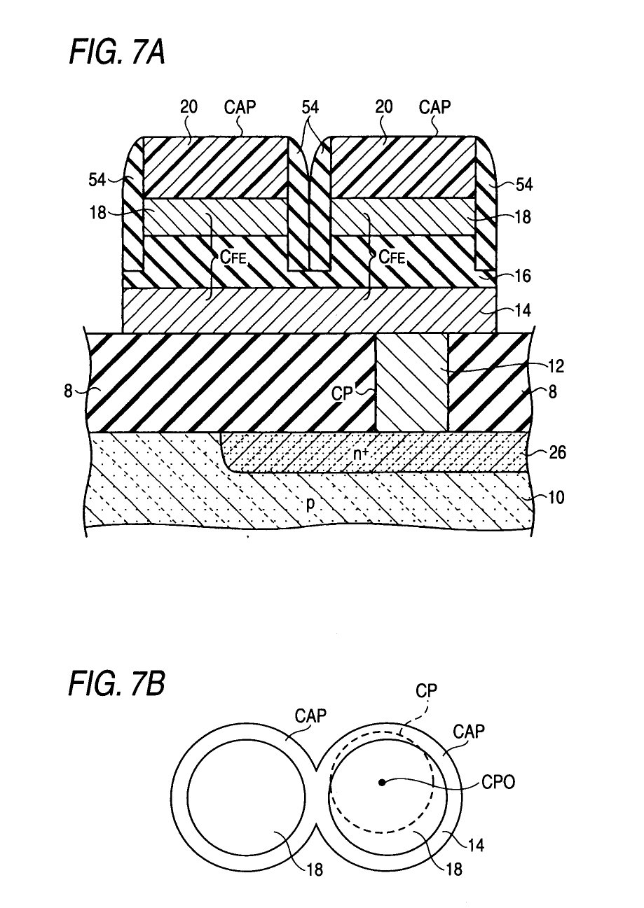

FIG. 7A schematically and cross-sectionally illustrates the configuration of a semiconductor device according to a third embodiment. FIG. 7B illustrates a schematic planar pattern of the vicinity of each of a capacitor CAP and a contact plug portion CP of the semiconductor device.

As shown in FIG. 7A, the semiconductor device according to the third embodiment includes a semiconductor substrate 10, transistors MT disposed on the semiconductor substrate 10, each of which has source-drain diffusion layer 26, an interlayer insulating film 8 disposed on the transistors MT, a plug electrode 12 disposed on the source-drain diffusion layer 26, and a plurality of ferroelectric capacitors C_{FE}, each of which includes a lower electrode 14, a ferroelectric film 16, and an upper electrode 18. The plurality of ferroelectric capacitors are paired two by two so that the ferroelectric capacitors C_{FE} of each pair have a common one of the lower electrodes 14 and individual ones of the upper electrodes 18, that the plug electrode is disposed just under one of each of the pairs of the ferroelectric capacitors C_{FE}, and that the entire surface of each of the plug electrodes 12 is covered by the lower electrodes 14.

In this case, a center CPO of the contact plug portion CP (the plug electrode 12) is covered by one of the upper electrodes 18 as viewed in a direction perpendicular to a surface of the semiconductor substrate 10.

As is illustrated in the schematic cross-sectional view of the semiconductor according to the third embodiment shown in FIG. 7A, each of the pair of the ferroelectric capacitors C_{FE} are physically connected with each other through a part of the ferroelectric film 16 and the lower electrode 14.

Also, as is illustrated in the schematic cross-sectional view of the semiconductor according to the third embodiment shown in FIG. 7A, each pair of the ferroelectric capacitors has a configuration in which a side wall mask 54 is disposed on the upper electrode 18 and a part of the ferroelectric film 16.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

In the semiconductor device according to the third embodiment, each pair of the ferroelectric capacitors having the lower electrode 14 in common can be formed by performing Two-Mask Photo-Engraving Process (PEP) (hereunder referred to as a 2-Mask-1-PEP).

That is, as illustrated in FIG. 7A, in a single lithographic process (1-PEP), a hard mask 20 is formed on each of the upper electrodes 18 as a first mask. Processing is performed on a part of each of the upper electrode 18 and the ferroelectric film 16. Subsequently, a side wall mask 54 is formed on a part of each of the hard mask 20, the upper electrode 18, and the ferroelectric film 16 as a second mask. Then, the rest of each of the ferroelectric film 16 and the lower electrode 14 is processed. As shown in FIG. 7B, each of the plug electrodes 12 is disposed just under one of the ferroelectric capacitors of an associated pair.

The ferroelectric capacitors of each pair share the lower electrode 14 and the ferroelectric film 16 in common. Thus, each of pair of the capacitors CAP is disposed to be in physically contact with each other through the shared portions of the lower electrode 14 and the ferroelectric film 16. Also, the contact plug portion CP is disposed just under one of the paired ferroelectric capacitors. Thus, the contact plug portion CP is disposed to be covered by one of the capacitor portions CAP.

In the capacitor structure of the semiconductor device according to the third embodiment, as shown in FIGS. 7A and 7B, the electrically conductive plug electrode 12 is disposed just under the capacitor portion CAP of one of the paired ferroelectric capacitors having the lower electrode 14 in common. This plug electrode 12 is electrically connected to the diffusion layer 26.

For example, SrRuO₃ or IrO₂ can be used as the material of the upper electrode 18 of the ferroelectric capacitor C_{FE}. For instance, PZT(Pb(Zr_{X}Ti_{1-X})O₃) can be used as the material of the ferroelectric film 16 of the ferroelectric capacitor C_{FE}. For example, SrRuO₃, Pt, IrO₂, Ir, Ti can be used as the lower electrode 14 of the ferroelectric capacitor C_{FE}.

The hardmask 20 is disposed on the ferroelectric capacitor C_{FE} so as to process collectively the ferroelectric capacitor structures including the upper electrode 18, the ferroelectric film 16, and the lower electrode 14 by performing the 1-Mask-1-PEP. Incidentally, a silicon dioxide film (SiO₂), an aluminum oxide film (Al_{X}O_{Y}), a zirconium oxide film (ZrO_{X}), a titanium oxide film (TiO_{X}), a titanium aluminum nitride film (TiAl_{X}N_{Y}), a titanium nitride film (Ti_{X}N_{Y}), a titanium aluminum nitride oxide film (TiAl_{X}N_{Y}O_{Z}), a titanium nitride oxide film (Ti_{X}N_{Y}O_{Z}), or a multilayer film including these films can be used as the material of the hard mask 20. It is advisable to select a material, whose etching-selectivity is larger than that of each of the upper electrode 18, the ferroelectric film 16, and the lower electrode 14, as the material of the hard mask 20.

A silicon dioxide film (SiO₂), an aluminum oxide film (Al_{X}O_{Y}), a zirconium oxide film (ZrO_{X}), a titanium oxide film (TiO_{X}), a titanium aluminum nitride film (TiAl_{X}N_{Y}), a titanium nitride film (Ti_{X}N_{Y}), a titanium aluminum nitride oxide film (TiAl_{X}N_{Y}O_{Z}), a titanium nitride oxide film (Ti_{X}N_{Y}O_{Z}), or a multilayer film including these films can be used as the material of the side wall mask 54 formed as the second mask on a side wall portion of a part of each of the hard mask 20, the upper electrode 18, and the ferroelectric film 16.

It is advisable to select a material, whose etching-selectivity is larger than that of each of the ferroelectric film 16, and the lower electrode 14, as the material of the side wall mask 54.

Also, it is advisable to set the distance between the ferroelectric capacitors of each pair, the lower electrodes 14 of which are connected to the same diffusion layer 26, so that the lower electrodes 14 are physically contacted with each other after the capacitor portions CAP are collectively processed by performing the 1-MASk-1-PEP.

Consequently, it is sufficient to dispose one contact plug portion CP corresponding to a pair of capacitor portions CAP, without disposing one contact plug portion CP corresponding to one capacitor portion CAP. Thus, the memory cell size can be reduced.

At that time, each of the contact plug portions CP is disposed under one of the capacitor portions CAP of an associated pair so that the entire surface of the plug electrode 12 is covered by the lower electrode 14, and that the surface of the plug electrode 12 is surely disposed immediately under the lower electrode 14.

Occurrences of the explosion of the W-plug, and high-increase in the resistance of each of the plug electrode 12 and the lower electrode 14 can be suppressed, and the fabrication yield can be enhanced by applying this configuration to the device, for example, in a case where the W-plug electrode is employed as the plug electrode 12.

The semiconductor device according to the third embodiment can be applied to a Chain-FeRAM™ having a minute 1-PEP_FeRAM capacitor structure, similarly to the first and second embodiments.

The side wall portions of the capacitor portions CAP, each of which includes the upper electrode 18, the ferroelectric film 16, and the lower electrode 14, can be protected by the side wall mask 54. A leakage current of the ferroelectric capacitor C_{FE} can be reduced. An amount of signal charge stored in the ferroelectric capacitor C_{FE} can be increased. The S/N at reading can be increased.

Also, a minute capacitor structure can be formed by utilizing both the hard mask 20, which is disposed on each of the two upper electrodes 18, and the side wall mask 54 disposed on the side wall portions. Consequently, the reliability and the fabrication yield of the device can be enhanced.

### Fourth Embodiment

Basic configuration

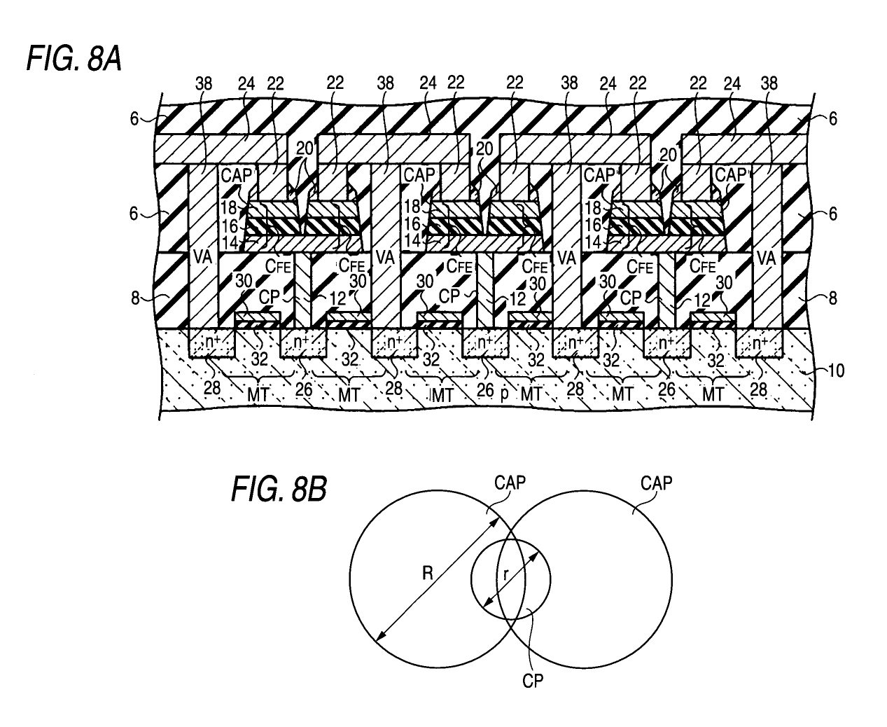

FIG. 8A schematically and cross-sectionally illustrates the configuration of a semiconductor device according to a fourth embodiment. FIG. 8B illustrates a schematic planar pattern of the vicinity of each of a capacitor CAP and a contact plug portion CP of the semiconductor device.

In the semiconductor device according to the fourth embodiment, the relationship between the diameter size R of the lower electrode 14 and the diameter size r of the plug electrode 12 is set as illustrated in FIG. 8B.

In the semiconductor device according to the fourth embodiment, the diameter size r of the plug electrode 12 is set to be equal to or less than ½ of the diameter size R of the lower electrode 14. Thus, the plug electrode 12 is disposed so that even when misalignment occurs, the plug electrode 12 is not exposed from the lower electrode 14.

The semiconductor device according to the fourth embodiment can be applied to a case where the diameter size R of the capacitor portion CAP is equal to or larger than the twice of the diameter size r of the plug electrode 12 that is the minimum size allowed by the design rule.

As shown in FIG. 8A, the semiconductor device according to the fourth embodiment includes a semiconductor substrate 10, transistors MT disposed on the semiconductor substrate 10, each of which has source-drain diffusion layers 26, 28, a gate insulating film 32 placed on the semiconductor substrate 10 between the source-drain diffusion layers 26 and 28, and a gate electrode 30 placed on the gate insulating film 32, an interlayer insulating film 8 disposed on the transistors MT, a plug electrode 12 disposed on one 26 of the source-drain diffusion layers that each of the transistors has, and a plurality of ferroelectric capacitors C_{FE}, each of which includes a lower electrode 14, a ferroelectric film 16, and an upper electrode 18. The plurality of ferroelectric capacitors are paired two by two so that the ferroelectric capacitors C_{FE} of each pair have a common one of the lower electrodes 14 and individual ones of the upper electrodes 18, that the plug electrode is disposed just under the center of each of the pairs of the ferroelectric capacitors C_{FE}, and that the entire surface of each of the plug electrodes 12 is covered by the lower electrodes 14.

Also, the semiconductor device according to the fourth embodiment features that the diameter size r of the plug electrode 12 is equal to or less than 50% of the diameter size R of the capacitor portion CAP.

Also, as shown in FIG. 8A, an interlayer insulating film 6 is disposed on the interlayer insulating film 8. A plurality of capacitors CAP having the lower electrode 14, the ferroelectric film 16 and the upper electrode 18, are disposed in the interlayer insulating film 6 by being embedded therein.

Additionally, as shown in FIG. 8A, a viahole electrode 22 is placed through a contact hole formed in a hard mask 20 that is disposed on the upper electrode 18. The viahole electrode 22 is connected to a wiring electrode 24, together with a viahole electrode 38 placed on the other 28 of the source-drain diffusion layers 26 and 28.

In the semiconductor according to the fourth embodiment, each of the pair of the ferroelectric capacitors C_{FE} are physically connected with each other through a part of the ferroelectric film 16 and the lower electrode 14.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

The ferroelectric capacitors of each pair share the lower electrode 14 in common. Thus, each of pair of the capacitors CAP is disposed to be in physically contact with each other through the shared portion of the lower electrode 14. Also, the contact plug portion CP is disposed just under the center of the paired ferroelectric capacitors. Thus, the contact plug portion CP is disposed to be covered by the capacitor portions CAP.

In the capacitor structure of the semiconductor device according to the fourth embodiment, as shown in FIGS. 8A and 8B, the electrically conductive plug electrode 12 is disposed just under the center of the pair of the capacitor portions CAP of the paired ferroelectric capacitors having the lower electrode 14 in common. This plug electrode 12 is electrically connected to the diffusion layer 26 that is one of the source-drain diffusion layers 26, 28.

In a case where the capacitor structure of the semiconductor device according to the fourth embodiment is employed, the fabrication yield is kept high while using the configuration in which the plug electrode is disposed substantially at the center of a pair of ferroelectric capacitors having the lower electrode 14 and the ferroelectric film 16 in common. Also, the density can be enhanced still more, as will be described later.

For example, SrRuO₃ or IrO₂ can be used as the material of the upper electrode 18 of the ferroelectric capacitor C_{FE}. For instance, PZT(Pb(Zr_{X}Ti_{1-X})O₃) can be used as the material of the ferroelectric film 16 of the ferroelectric capacitor C_{FE}. For example, SrRuO₃, Pt, IrO₂, Ir, Ti can be used as the lower electrode 14 of the ferroelectric capacitor C_{FE}.

The hard mask 20 is disposed on the ferroelectric capacitor C_{FE} so as to process collectively the ferroelectric capacitor structures including the upper electrode 18, the ferroelectric film 16, and the lower electrode 14 by performing the 1-Mask-1-PEP. Incidentally, a silicon dioxide film (SiO₂), an aluminum oxide film (Al_{X}O_{Y}), a zirconium oxide film (ZrO_{X}), a titanium oxide film (TiO_{X}), a titanium aluminum nitride film (TiAl_{X}N_{Y}), a titanium nitride film (Ti_{X}N_{Y}), a titanium aluminum nitride oxide film (TiAl_{X}N_{Y}O_{Z}), a titanium nitride oxide film (TiₓN_{Y}O_{Z}), or a multilayer film including these films can be used as the material of the hard mask 20. It is advisable to select a material, whose etching-selectivity is larger than that of each of the upper electrode 18, the ferroelectric film 16, and the lower electrode 14, as the material of the hard mask 20.

Also, it is advisable to set the distance between the ferroelectric capacitors of each pair, the lower electrodes 14 of which are connected to a same diffusion layer 26, so that the lower electrodes 14 are physically contacted with each other after the capacitor portions CAP are collectively processed by performing the 1-MASk-1-PEP.

Consequently, it is sufficient to dispose one contact plug portion CP corresponding to a pair of capacitor portions CAP, without disposing one contact plug portion CP corresponding to one capacitor portion CAP. Thus, the memory cell size can be reduced.

At that time, each of the contact plug portions CP is disposed under the center of the capacitor portions CAP of an associated pair so that the entire surface of the plug electrode 12 is covered by the lower electrode 14, and that the surface of the plug electrode 12 is surely disposed immediately under the lower electrode 14.

Occurrences of the explosion of the W-plug, and high-increase in the resistance of each of the plug electrode 12 and the lower electrode 14 can be suppressed, and the fabrication yield can be enhanced by applying this configuration to the device, for example, in a case where the W-plug electrode is employed as the plug electrode 12.

In the semiconductor device according to the fourth embodiment, a minute capacitor structure can be provided, which is used in a Chain-FeRAM™ having a 1-PEP_FeRAM capacitor structure, and which enhances the fabrication yield thereof.

In the semiconductor according to the fourth embodiment, the plug electrode 12 may be disposed under one of the capacitor portions CAP of the associated pair.

### Fifth Embodiment

Basic configuration

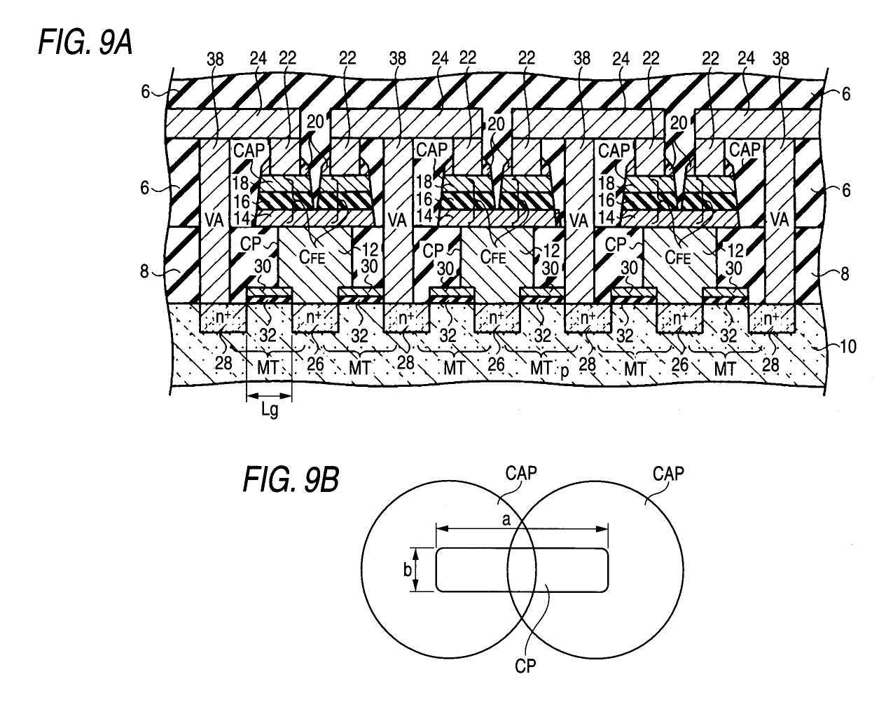

FIG. 9A schematically and cross-sectionally illustrates the configuration of a semiconductor device according to a fifth embodiment. FIG. 9B illustrates a schematic planar pattern of the vicinity of each of a capacitor CAP and a contact plug portion CP of the semiconductor device.

In the semiconductor device according to the fifth embodiment, the relationship between the diameter size R of the lower electrode 14 and the size of the plug electrode 12 is set similarly to the fourth embodiment.

That is, the semiconductor device according to the fifth embodiment employs a rectangle, whose longer side having a length a and whose shorter side having a length b, as the shape of the contact plug portion CP so as to reduce the contact resistance between the lower electrode 14 and the plug electrode 12 by increasing the contact area between the lower electrode 14 and the contact plug portion CP, as shown in FIG. 9B. The semiconductor device according to the fifth embodiment is configured so that the diameter size R of the ferroelectric capacitors of each pair and the lengths a and b of longer and shorter sides of the plug electrode 12 meet the following conditions: R>2b; and 2R>a>R. Also, as shown in FIG. 9B, the cross-sectionally rectangular contact plug portion CP is disposed substantially at the central portion between the ferroelectric capacitors of each pair. Consequently, the resistance between the plug electrode 12 and the lower electrode 14 is suppressed to a low value. Accordingly, the fabrication yield can be improved.

In this case, as shown in FIGS. 9A and 9B, the memory cell transistor MT has the gate length of about Lg. The length b of the shorter side of the plug electrode 12 is equal to or larger than the gate length Lg of the memory cell transistor.

As shown in FIG. 9A, the semiconductor device according to the fifth embodiment includes a semiconductor substrate 10, transistors MT disposed on the semiconductor substrate 10, each of which has source-drain diffusion layers 26, 28, a gate insulating film 32 placed on the semiconductor substrate 10 between the source-drain diffusion layers 26 and 28, and a gate electrode 30 placed on the gate insulating film 32, an interlayer insulating film 8 disposed on the transistors MT, a plug electrode 12 disposed on one 26 of the source-drain diffusion layers that each of the transistors has, and a plurality of ferroelectric capacitors C_{FE}, each of which includes a lower electrode 14, a ferroelectric film 16, and an upper electrode 18. The plurality of ferroelectric capacitors are paired two by two so that the ferroelectric capacitors C_{FE} of each pair have a common one of the lower electrodes 14 and individual ones of the upper electrodes 18, that the plug electrode is disposed just under the center of each of the pairs of the ferroelectric capacitors C_{FE}, and that the entire surface of each of the plug electrodes 12 is covered by the lower electrodes 14.

In the semiconductor device according to the fifth embodiment, the shape of the plug electrode 12 is a rectangle whose longer side having a length a and whose shorter side having a length b, as shown in FIG. 9B, and that the diameter size R of the ferroelectric capacitors of each pair and the lengths a and b of longer and shorter sides of the plug electrode 12 meet the following conditions: R>2b; and 2R>a>R.

Also, as shown in FIG. 9A, an interlayer insulating film 6 is disposed on the interlayer insulating film 8. A plurality of capacitors CAP having the lower electrode 14, the ferroelectric film 16 and the upper electrode 18, are disposed in the interlayer insulating film 6 by being embedded therein.

Additionally, as shown in FIG. 9A, a viahole electrode 22 is placed through a contact hole formed in a hard mask 20 that is disposed on the upper electrode 18. The viahole electrode 22 is connected to a wiring electrode 24, together with a viahole electrode 38 placed on the other 28 of the source-drain diffusion layers 26 and 28.

In the semiconductor according to the fifth embodiment, each of the pair of the ferroelectric capacitors C_{FE} are physically connected with each other through a part of the ferroelectric film 16 and the lower electrode 14.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

The ferroelectric capacitors of each pair share the lower electrode 14 in common. Thus, each of pair of the capacitors CAP is disposed to be in physically contact with each other through the shared portion of the lower electrode 14. Also, the contact plug portion CP is disposed just under the center of the paired ferroelectric capacitors. Thus, the contact plug portion CP is disposed to be covered by the capacitor portions CAP.

In the capacitor structure of the semiconductor device according to the fifth embodiment, as shown in FIG. 9A, the electrically conductive plug electrode 12 is disposed just under the center of the pair of the capacitor portions CAP of the paired ferroelectric capacitors having the lower electrode 14 in common. This plug electrode 12 is electrically connected to the diffusion layer 26 that is one of the source-drain diffusion layers 26, 28.

In a case where the capacitor structure of the semiconductor device according to the fifth embodiment is employed, the fabrication yield is kept high while using the configuration in which the plug electrode is disposed substantially at the center of a pair of ferroelectric capacitors having the lower electrode 14 and the ferroelectric film 16 in common. Also, the density can be enhanced still more, as will be described later.

For example, SrRuO₃ or IrO₂ can be used as the material of the upper electrode 18 of the ferroelectric capacitor C_{FE}. For instance, PZT(Pb(Zr_{X}Ti_{1-X})O₃) can be used as the material of the ferroelectric film 16 of the ferroelectric capacitor C_{FE}. For example, SrRuO₃, Pt, IrO₂, Ir, Ti can be used as the lower electrode 14 of the ferroelectric capacitor C_{FE}.

The hard mask 20 is disposed on the ferroelectric capacitor C_{FE} so as to process collectively the ferroelectric capacitor structures including the upper electrode 18, the ferroelectric film 16, and the lower electrode 14 by performing the 1-Mask-1-PEP. Incidentally, a silicon dioxide film (SiO₂), an aluminum oxide film (Al_{X}O_{Y}), a zirconium oxide film (ZrO_{X}), a titanium oxide film (TiO_{X}) a titanium aluminum nitride film (TiAl_{X}N_{Y}), a titanium nitride film (Ti_{X}N_{Y}), a titanium aluminum nitride oxide film (TiAl_{X}N_{Y}O_{Z}), a titanium nitride oxide film (Ti_{X}N_{Y}O_{Z}), or a multilayer film including these films can be used as the material of the hard mask 20. It is advisable to select a material, whose etching-selectivity is larger than that of each of the upper electrode 18, the ferroelectric film 16, and the lower electrode 14, as the material of the hard mask 20.

Also, it is advisable to set the distance between the ferroelectric capacitors of each pair, the lower electrodes 14 of which are connected to a same diffusion layer 26, so that the lower electrodes 14 are physically contacted with each other after the capacitor portions CAP are collectively processed by performing the 1-MASk-1-PEP.

Consequently, it is sufficient to dispose one contact plug portion CP corresponding to a pair of capacitor portions CAP, without disposing one contact plug portion CP corresponding to one capacitor portion CAP. Thus, the memory cell size can be reduced.

At that time, each of the contact plug portions CP is disposed under the center of the capacitor portions CAP of an associated pair so that the entire surface of the plug electrode 12 is covered by the lower electrode 14, and that the surface of the plug electrode 12 is surely disposed immediately under the lower electrode 14.

Occurrences of the explosion of the W-plug, and high-increase in the resistance of each of the plug electrode 12 and the lower electrode 14 can be suppressed, and the fabrication yield can be enhanced by applying this configuration to the device, for example, in a case where the W-plug electrode is employed as the plug electrode 12.

Most Dense Configuration

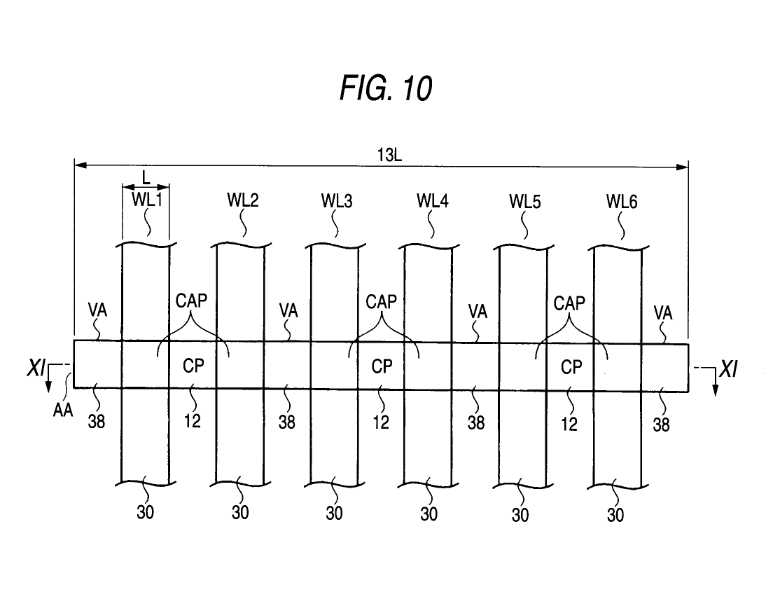

In a case where the semiconductor device according to the fifth embodiment is configured in the most dense configuration, and where, for example, six memory cell transistors MT are disposed in series in a Chain-FeRAM™ structure, the schematic planar pattern configuration is such that the semiconductor device has an active region AA extending in a column direction and also has word lines WL1 to WL6 extending in a row direction perpendicular to the active region AA, as shown in FIG. 10. FIG. 11 is a schematic cross-sectional view illustrating the configuration of the semiconductor device, which is taken along line XI-XI shown in FIG. 10.

In FIGS. 9A to 11, a region to be shown as the viahole electrode 38 is designated as a viahole contact portion VA. Also, a region to be shown as the plug electrode 12 is designated as a contact plug portion CP. Additionally, a region to be shown as the ferroelectric capacitor C_{FE} including the lower electrode 14, the ferroelectric film 16, and the upper electrode 18, is designated as the capacitor portion CAP.

In a case where the six memory cell transistors MT are disposed in series in the Chain-FeRAM™ configuration, and where L denotes the minimum line width, the memory cell transistors MT are placed within a dimension of 16L, as illustrated in FIG. 10. The source-drain diffusion layers 26, 28 of each of the memory cell transistors MT, are arranged in the active region AA. Also, a channel region corresponding to each of portions of the semiconductor substrate 10, each of which is provided between the associated source-drain diffusion layers 26, 28, is placed in the active region AA. In the example shown in FIG. 10, the channel region is disposed in an intersection portion at which the active region AA intersects with each of the word lines WL1 to WL6. Although FIG. 10 shows only one active region AA of the example, a plurality of active regions AA extend in the column direction in parallel to one another on a memory cell array.

As shown in FIG. 11, the semiconductor device according to the fifth embodiment in the most dense configuration, in which the six memory cell transistors MT are disposed in series in the Chain-FeRAM™ structure, includes a semiconductor substrate 10, transistors MT disposed on the semiconductor substrate 10, each of which has the source-drain diffusion layers 26, 28, a gate insulating film 32 placed on the semiconductor substrate 10 between the source-drain diffusion layers 26 and 28, and the gate electrode 30 placed on the gate insulating film 32, the interlayer insulating film 8 disposed on the transistors MT, the plug electrode 12 disposed on one 26 of the source-drain diffusion layers that each of the transistors has, and a plurality of ferroelectric capacitors C_{FE}, each of which includes a lower electrode 14, a ferroelectric film 16, and an upper electrode 18. The plurality of ferroelectric capacitors are paired two by two so that the ferroelectric capacitors of each pair have a common one of the lower electrodes 14 and individual ones of the upper electrodes 18, that the plug electrode 12 is disposed just under the center of each of the pairs of the ferroelectric capacitors C_{FE}, and that the entire surface of each of the plug electrodes 12 is covered by the lower electrodes 14.

Also, the shape of the plug electrode 12 is a rectangle whose longer side having a length a and whose shorter side having a length b, and that the diameter size R of the ferroelectric capacitors of each pair and the lengths a and b of longer and shorter sides of the plug electrode 12 meet the following conditions: R>2b; and 2R>a>R.

Additionally, the length b of the shorter side of the plug electrode 12 is equal to or larger than the gate length Lg of the memory cell transistor.

Also, as shown in FIG. 11, an interlayer insulating film 6 is disposed on the interlayer insulating film 8. A plurality of capacitors CAP having the lower electrode 14, the ferroelectric film 16 and the upper electrode 18, are disposed in the interlayer insulating film 6 by being embedded therein.

Additionally, as shown in FIG. 11, each of wiring electrode 24 is disposed on an associated one of the upper electrodes 18 to be contacted directly with the associated upper electrode 18. Each of the wiring electrodes 24 is connected to a viahole electrode 38 that is placed on the other 28 of the source-drain diffusion layers 26 and 28 by being sandwiched by the side wall insulating films 56. Thus, a Chain-FeRAM™ is constituted.

Each of the pair of the ferroelectric capacitors C_{FE} are physically connected with each other through a part of the ferroelectric film 16 and the lower electrode 14.

Alternatively, each of the pairs of ferroelectric capacitors C_{FE} may be physically connected with each other only through a part of the lower electrodes. Additionally, the ferroelectric film 16 is separated in two parts, and the depression is formed on the upper surface of the lower electrode 14.

In the semiconductor device according to the fifth embodiment, a minute capacitor structure can be provided, which is used in a Chain-FeRAM™ having a 1-PEP_FeRAM capacitor structure, and which enhances the fabrication yield thereof.

Memory Cell Array

Configuration of Chain-FeRAM™

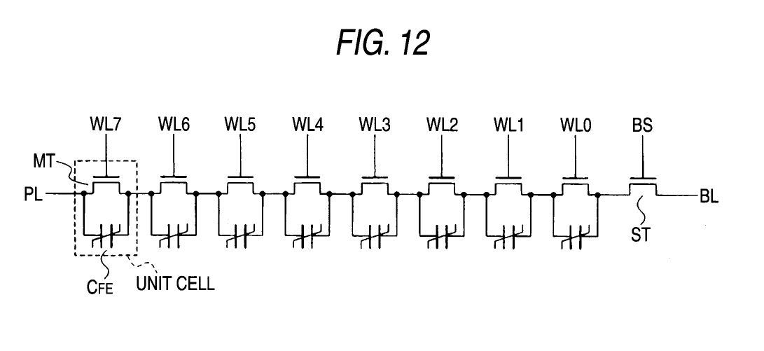

FIG. 12 schematically illustrates the circuit configuration of a Chain-FeRAM™ cell block, to which each of the semiconductor devices according to the first to fifth embodiments can be applied, and in which a plurality of unit cells are series-connected. The Chain-FeRAM™ is configured so that unit cells, each of which is constituted by parallel-connecting the memory cell transistors MT and the ferroelectric capacitors C_{FE}, are series-connected. Therefore, the Chain-FeRAM™ is called a “TC unit series-connected FeRAM”.

As shown in, for example, FIG. 12, the unit cell of the Chain-FeRAM™ has a configuration in which both terminals of the ferroelectric capacitor C_{FE} are connected to the source and the drain of the memory cell transistor MT, respectively. A plurality of such unit cells are disposed in series between a plate line PL and a bit line BL. A block selection transistor ST selects one of a plurality of series-connected Chain-FeRAM™ strings or blocks. The gate of each of the memory cell transistors MTs is connected to an associated one of word lines WL0, WL1, WL2, . . . , WL7. A block selection line BS is connected to the gate of the block selection transistor ST.

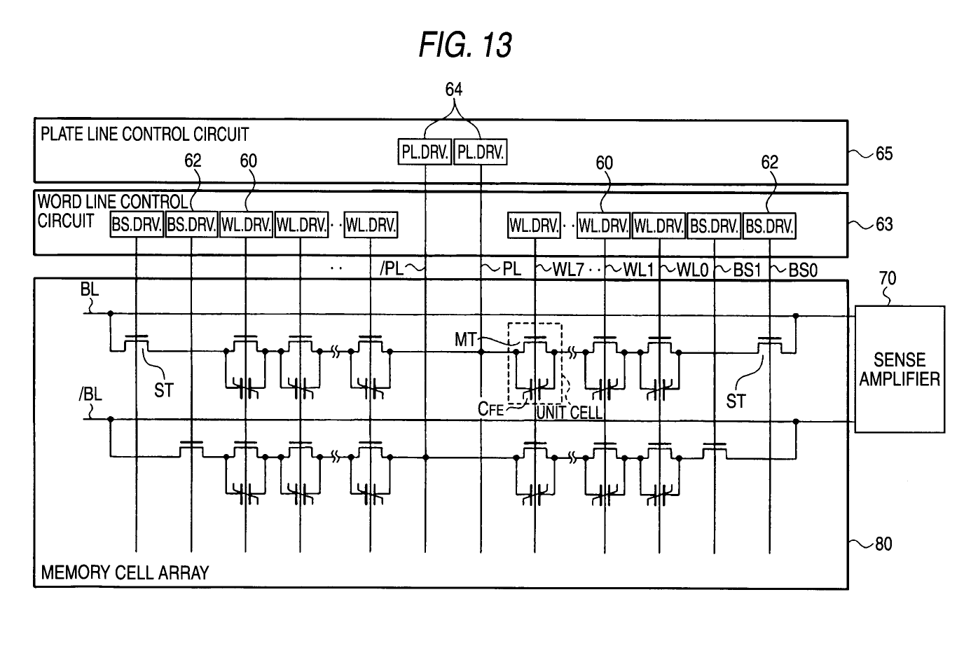

FIG. 13 schematically illustrates the block configuration of a Chain-FeRAM™ cell array that is an example of a memory cell array to which each of the semiconductor devices according to the first to fifth embodiments of the invention can be applied. As shown in FIG. 13, the Chain-FeRAM™ cell array has a memory cell array 80, a word line control circuit 63 connected to the memory cell array 80, and a plate line control circuit 65 connected to the word line control circuit 63. In the memory cell array 80, a plurality of Chain-FeRAM™ cells are arranged like a matrix.

As shown in FIG. 13, a plurality of word lines WL (WL0 to WL7) are respectively connected to word line drivers (WL.DRV.) 60 arranged in the word line control circuit 63. Block selection lines BS (BS0, BS1) are respectively connected to block selection line drivers (BS.DRV.) 62 arranged in the word line control circuit 63. On the other hand, plate lines PL (PL, /PL) are respectively connected to plate line drivers (PL.DRV.) 64 arranged in the plate line control circuit 65.

As shown in FIG. 13, the memory cell array 80 has a configuration in which the Chain-FeRAM™ blocks are disposed in parallel in a direction in which the word lines WL (WL0 to WL7) extends. Also, as shown in FIG. 13, the memory cell array 80 is configured so that the Chain-FeRAM™ blocks are arranged in the direction, in which the bit lines BL (BL, /BL) extend, to be symmetrical with respect to a center line between the plate lines PL (PL, /PL).

In the Chain-FeRAM™, the potential V (WL) on each of the word lines WL (WL0 to WL7) and the potential V (BS) on the block selection lines BS (BS0, BS1) are an internal power supply voltage VPP or a ground potential GND, for example, 0 V. Also, in a standby state, for example, the potential V on the word lines WL is equal to the internal power supply voltage VPP. The voltage V on the block selection line BS is equal to 0 (V). The potential V (PL) on the plate lines PL (PL. /PL) us equal to an internal power supply voltage VINT or to the ground potential GND. Additionally, in the standby state, the potential V(PL)=0 (V).

A sense amplifier 70 is connected to the bit lines BL (BL. /BL). The sense amplifier 70 performs comparison-amplification on weak signals output from the FeRAM unit cells. Then, signals, whose levels are determined to be a high level or a low level, are read therefrom. In the standby state, the potential V(BL)=0 (V).

### Other Embodiments

Although the present invention has been described in the descriptions of the first to fifth embodiments thereof, it should not be understood that the description and the drawings constituting a part of the disclosure of the present invention limit this invention. Various alternative embodiments, examples and operation techniques will become apparent from this disclosure to those skilled in the art.

For example, the semiconductor device according to the invention is not limited to the Chain-FeRAM™. The semiconductor device according to the invention may be either a DRAM type FeRAM in which a ferroelectric capacitor C_{FE} is series-connected to a source-drain diffusion layer of a memory cell transistor, or a 1T type FeRAM having a ferroelectric capacitor C_{FE} as a gate capacitor.

Thus, it is apparent that the invention includes various embodiments which are not described herein. Accordingly, the scope of the invention will be defined only by appropriate particulars specifying the invention according to the appended claims on the basis of the foregoing description thereof.

As described above, a minute capacitor structure which is used in a Chain-FeRAM™ having a 1-PEP_FeRAM capacitor structure, and which enhances a fabrication yield thereof is provided.

What is claimed is:

1. A semiconductor device comprising:
a semiconductor substrate;
a transistor comprising:
a first diffusion layer disposed on the semiconductor substrate,
a second diffusion layer disposed on the semiconductor substrate,
a gate insulating film disposed between the first diffusion layer and the second diffusion layer and on the semiconductor substrate, and
a gate electrode disposed on the gate insulating film;
an interlayer insulating film disposed on the semiconductor substrate and on the transistor;
a plug electrode that is connected to the first diffusion layer and disposed in the interlayer insulating film; and
a capacitor unit comprising:
a lower electrode that is disposed on the interlayer insulating film and that covers atop face of the plug electrode,
a ferroelectric film disposed on the lower electrode,
a first upper electrode disposed on the ferroelectric film, and
a second upper electrode disposed on the ferroelectric film and separated from the first upper electrode;
wherein the first upper electrode covers a center of the plug electrode as viewed in a direction perpendicular to a surface of the semiconductor substrate.

2. The semiconductor device according to claim 1, wherein the lower electrode comprises:
a first circular portion that covers the top face and that is opposite to the first upper electrode; and
a second circular portion that is electrically connected with the first circular portion and that is opposite to the second upper electrode.

3. The semiconductor device according to claim 2, wherein the first circular portion has a diameter of about R;
wherein the plug electrode is formed in a cylindrical shape having a diameter of about r; and
wherein R and r satisfy R≧2r.

4. The semiconductor device according to claim 3, wherein the transistor has a gate length of about Lg; and
wherein r and Lg satisfy r≧Lg.

5. The semiconductor device according to claim 2, wherein the capacitor unit comprises:
a first ferroelectric capacitor formed between the first circular portion and the first upper electrode; and
a second ferroelectric capacitor formed between the second circular portion and the second upper electrode.

6. The semiconductor device according to claim 5, wherein the first ferroelectric capacitor and the transistor form a first memory cell.

7. The semiconductor device according to claim 6 further comprising a second transistor that shares the first diffusion layer with the transistor;
wherein the second ferroelectric capacitor and the second transistor form a second memory cell.

8. The semiconductor device according to claim 1, wherein the lower electrode comprises a depression between the first upper electrode and the second upper electrode on an upper surface of the lower electrode.

9. The semiconductor device according to claim 1, wherein the capacitor unit further comprises a side wall mask that is disposed along a side surface of the first upper electrode and the second upper electrode.

10. The semiconductor device according to claim 1, wherein the capacitor unit is formed by 1-Mask-1-PEP.

11. A semiconductor device comprising:
a semiconductor substrate;
a transistor comprising:
a first diffusion layer disposed on the semiconductor substrate,
a second diffusion layer disposed on the semiconductor substrate,
a gate insulating film disposed between the first diffusion layer and the second diffusion layer and on the semiconductor substrate, and
a gate electrode disposed on the gate insulating film;
an interlayer insulating film disposed on the semiconductor substrate and on the transistor;
a plug electrode that is connected to the first diffusion layer and disposed in the interlayer insulating film; and
a capacitor unit comprising:
a lower electrode that is disposed on the interlayer insulating film to cover a top face of the plug electrode such that a center of the lower electrode is arranged on the top face,
a ferroelectric film disposed on the lower electrode,
a first upper electrode disposed on the ferroelectric film, and
a second upper electrode disposed on the ferroelectric film and separated from the first upper electrode;
wherein the lower electrode comprising:
a first circular portion disposed oppositely to the first upper electrode and having a diameter of about R, and
a second circular portion electrically connected with the first circular portion and disposed oppositely to the second upper electrode, the second circular portion having the diameter of about R;
wherein the plug electrode is formed in a rectangular shape having a long side length of about a and a short side length of about b; and
wherein R, a and b satisfy R>2b and 2R>a>R.

12. The semiconductor device according to claim 11, wherein the transistor has a gate length of about Lg; and
wherein b and Lg satisfy b≧Lg.

13. The semiconductor device according to claim 11, wherein the lower electrode comprises a depression between the first upper electrode and the second upper electrode on an upper surface of the lower electrode.

14. The semiconductor device according to claim 11, wherein the capacitor unit further comprises a side wall mask that is disposed along a side surface of the first upper electrode and the second upper electrode.

15. The semiconductor device according to claim 11, wherein the capacitor unit is formed by 1-Mask-1-PEP.

16. A semiconductor device comprising:
a semiconductor substrate;
an interlayer insulating film disposed on the semiconductor substrate;
a plug electrode disposed in the interlayer insulating film; and
a capacitor unit comprising:
a lower electrode that is disposed on the interlayer insulating film and connected with the plug electrode,
a ferroelectric film disposed on the lower electrode,
a first upper electrode disposed on the ferroelectric film, and
a second upper electrode disposed on the ferroelectric film and separated from the first upper electrode;
wherein the lower electrode comprising:
a first circular portion that covers a top face of the plug electrode and that is opposite to the first upper electrode, and
a second circular portion that is electrically connected with the first circular portion and that is opposite to the second upper electrode; and
wherein the plug electrode is disposed underneath only the first circular portion.

17. The semiconductor device according to claim 16, wherein the first circular portion has a diameter of about R;
wherein the plug electrode is formed in a cylindrical shape having a diameter of about r; and
wherein R and r satisfy R≧2r.

18. The semiconductor device according to claim 16, wherein the lower electrode comprises a depression between the first upper electrode and the second upper electrode on an upper surface of the lower electrode.

19. The semiconductor device according to claim 16, wherein the capacitor unit further comprises a side wall mask that is disposed along a side surface of the first upper electrode and the second upper electrode.

20. The semiconductor device according to claim 16, wherein the capacitor unit is formed by 1-Mask-1-PEP.
